(19) United States
(12) Patent Application Publication
(10) Pub. No.: US 2025/0379547 A1
(43) Pub. Date: Dec. 11, 2025

(54) RUGGED PEAK VOLTAGE LIMITING CIRCUITS

(71) Applicant: SKYWORKS SOLUTIONS, INC., Irvine, CA (US)

(72) Inventors: Anthony Francis Quaglietta, Methuen, MA (US); Joseph A. Cuggino, Westford, MA (US)

(21) Appl. No.: 19/192,035

(22) Filed: Apr. 28, 2025

Related U.S. Application Data
(60) Provisional application No. 63/640,050, filed on Apr. 29, 2024.

(51) Int. Cl. H03F 1/52; H03F 1/56; H03F 3/24

(52) U.S. Cl. CPC H03F 1/52; H03F 1/565; H03F 3/245; H03F 2200/435; H03F 2200/451

(57) ABSTRACT

A device may include a first diode circuit coupled to an output of an amplification stage of a power amplifier (PA). A device may include a first bias circuit. A device may include a first isolation resistor coupled to the first bias circuit. A device may include a first attenuation circuit coupled to the first isolation resistor, the first attenuation circuit comprising two or more resistors. A device may include a sink transistor coupled to the first diode circuit and the first attenuation circuit.

### CROSS-REFERENCE TO RELATED APPLICATIONS

This application claims priority to U.S. Provisional Application No. 63/640,050, filed Apr. 29, 2024, and entitled “RUGGED PEAK VOLTAGE LIMITING CIRCUITS” the entire contents of which are incorporated herein by reference.

### BACKGROUND

In some radio-frequency (RF) applications, amplifiers such as power amplifiers (PAs) are typically designed to function under normal operating conditions, and also survive under at least some abnormal conditions. Such survivability under abnormal operating conditions is typically referred to as ruggedness of the amplifier.

### SUMMARY

In accordance with some implementations, the present disclosure relates to a circuit including a first diode circuit coupled to an output of an amplification stage of a power amplifier (PA); a first bias circuit; a first isolation resistor coupled to the first bias circuit; a first attenuation circuit coupled to the first isolation resistor, the first attenuation circuit including two or more resistors; and a sink transistor coupled to the first diode circuit and the first attenuation circuit.

In some aspects, the circuit further includes a second diode circuit coupled to an emitter of the sink transistor. The second diode circuit may include a first diode, and wherein the emitter of the sink transistor is coupled to an anode of the first diode.

The first diode circuit may include a second diode, and wherein a base of the sink transistor is coupled to a cathode of the second diode. In some aspects, the first attenuation circuit is coupled to a collector of the sink transistor.

In some aspects, the first attenuation circuit includes a first resistor, a second resistor, and a third resistor, and wherein each of the first resistor, second resistor, and third resistor is coupled to a first node. The first bias circuit may include a bias transistor, and wherein the first isolation resistor is coupled to a base of the bias transistor.

The circuit may further include a second bias circuit, a second isolation resistor, and a second attenuation circuit, wherein the second bias circuit is coupled to the second isolation resistor, the second isolation resistor is coupled to the second attenuation circuit, and the second attenuation circuit is coupled to the sink transistor. In some aspects, the first bias circuit includes a bias transistor, and wherein the first isolation resistor is coupled to an emitter of the bias transistor.

In some aspects, the first diode circuit is configured to provide a conductive path from the output when an output voltage exceeds a selected value. The sink transistor may be configured to reduce a bias voltage provided by the first bias circuit when the output voltage exceeds the selected value.

Some implementations of the present disclosure relate to a power amplifier (PA) including a first diode circuit coupled to an output of an amplification stage; a first bias circuit; a first isolation resistor coupled to the first bias circuit; a first attenuation circuit coupled to the first isolation resistor, the first attenuation circuit including two or more resistors; and a sink transistor coupled to the first diode circuit and the first attenuation circuit.

In some aspects, the PA further includes a second diode circuit coupled to an emitter of the sink transistor. The first attenuation circuit may be coupled to a collector of the sink transistor.

The first attenuation circuit may include a first resistor, a second resistor, and a third resistor, and wherein each of the first resistor, second resistor, and third resistor is coupled to a first node. In some aspects, the first bias circuit includes a bias transistor, and wherein the first isolation resistor is coupled to a base of the bias transistor.

Some implementations of the present disclosure relate to a radio-frequency (RF) module including a packaging substrate configured to receive a plurality of components; and a power amplifier (PA) implemented on a die that is mounted on the packaging substrate, the PA including one or more amplification stages configured to amplify an RF signal, the PA further including a first diode circuit coupled to an output of an amplification stage of the one or more amplification stages, a first bias circuit, a first isolation resistor coupled to the first bias circuit, a first attenuation circuit coupled to the first isolation resistor, the first attenuation circuit including two or more resistors, and a sink transistor coupled to the first diode circuit and the first attenuation circuit.

In some aspects, the RF module further includes a second diode circuit coupled to an emitter of the sink transistor. The first attenuation circuit may be coupled to a collector of the sink transistor.

The first attenuation circuit may include a first resistor, a second resistor, and a third resistor, and wherein each of the first resistor, second resistor, and third resistor is coupled to a first node.

For purposes of summarizing the disclosure, certain aspects, advantages, and/or features of the disclosure have been described. It is to be understood that not necessarily all such advantages may be achieved in accordance with any particular embodiment of the disclosure. Thus, the disclosure may be embodied or carried out in a manner that achieves or optimizes one advantage or group of advantages as taught herein without necessarily achieving other advantages as may be taught or suggested herein.

### BRIEF DESCRIPTION OF THE DRAWINGS

Various embodiments are depicted in the accompanying drawings for illustrative purposes and should in no way be interpreted as limiting the scope of the disclosure. In addition, various features of different disclosed embodiments can be combined to form additional embodiments, which are part of this disclosure. Throughout the drawings, reference numbers may be reused to indicate correspondence between reference elements.

FIG. 1 depicts a power amplifier (PA) having one or more amplification stages configured to receive an input signal (RF_IN) and amplify it to generate an amplified signal (RF_OUT).

FIGS. 2A and 2B show examples of a circuit implemented for a PA system having three amplification stages.

FIG. 3 shows an example of a PA system having three amplification stages, but without a ruggedness protection circuit.

FIG. 4 shows an example of a ruggedness protection circuit implemented in the context of the example PA system of FIG. 3.

FIG. 5 shows a circuit that can include a group of one or more diodes arranged in series that couples a collector of the amplifying transistor.

FIG. 6 shows a more specific example of the peak voltage detection configuration of FIG. 5.

FIG. 7 shows another more specific example of the peak voltage detection configuration of FIG. 5.

FIG. 8 illustrates a circuit implemented in an example 3-stage PA system.

FIG. 9 illustrates a circuit implemented in an example 3-stage PA system.

FIG. 10 illustrates a circuit implemented in an example 3-stage PA system.

FIG. 11 illustrates a circuit implemented in an example 3-stage PA system.

FIG. 12 illustrates an example circuit comprising one or more components in accordance with one or more examples described herein.

FIG. 13 shows an example of how a collector voltage Vcc3 can be advantageously limited by a circuit having one or more features as described herein.

FIG. 14A shows performance plots without a PVL circuit.

FIG. 14B shows performance plots with a PVL circuit.

FIG. 15A shows gain profiles without a PVL circuit.

FIG. 15B shows gain profiles with a PVL circuit.

FIG. 16 depicts a die that can include a circuit having one or more features as described herein.

FIG. 17 schematically depicts an example module having a packaging substrate that is configured to receive a plurality of components.

FIG. 18 schematically depicts an example wireless device having one or more advantageous features described herein.

### DESCRIPTION

The headings provided herein, if any, are for convenience only and do not necessarily affect the scope or meaning of the claimed invention.

In some radio-frequency (RF) applications, amplifiers such as power amplifiers (PAs) are typically designed to function under normal operating conditions, and also survive under at least some abnormal conditions. Such survivability under abnormal operating conditions is typically referred to as ruggedness of the amplifier.

In many RF applications, survivability of amplifiers with voltage standing wave ratio (VSWR) of up to 10:1 and over temperature range extremes is typically expected. Amplifiers can be destroyed or damaged when producing large RF voltage swings. Such voltage swings can be maximized or enhanced at certain load phases and elevated VSWR conditions, as well as presence of a high level of input incident RF power level. Voltage maxima or peak produced under such extreme conditions can induce an avalanche current due to, for example, collector-base voltage (Vcb) breakdown in NPN devices. With such a breakdown, a device can be destroyed or suffer from non-recoverable damage.

In some situations, ruggedness of an amplifier can be an issue when the amplifier is operated outside of its intended range. For example, an amplifier can be designed to operate at a supply voltage (Vcc) of 3.6V, with possible operation at a maximum design limit of 4.6V. When such an amplifier is operated at 5V, its survival can be marginal even at room temperature. For example, such an amplifier can fail at room temperature from input power (Pin) range of −5 dBm to +5 dBm for VSWR of 6:1. It is noted that such failures typically occur at a phase closer to voltage peaking rather than current peaking.

In some implementations, the present disclosure relates to a peak voltage limiting (PVL) circuit that can be implemented in an amplifier such as a power amplifier (PA). Although various examples are described in the context of PAs, it will be understood that one or more features of the present disclosure can also be implemented in other types of RF amplifiers.

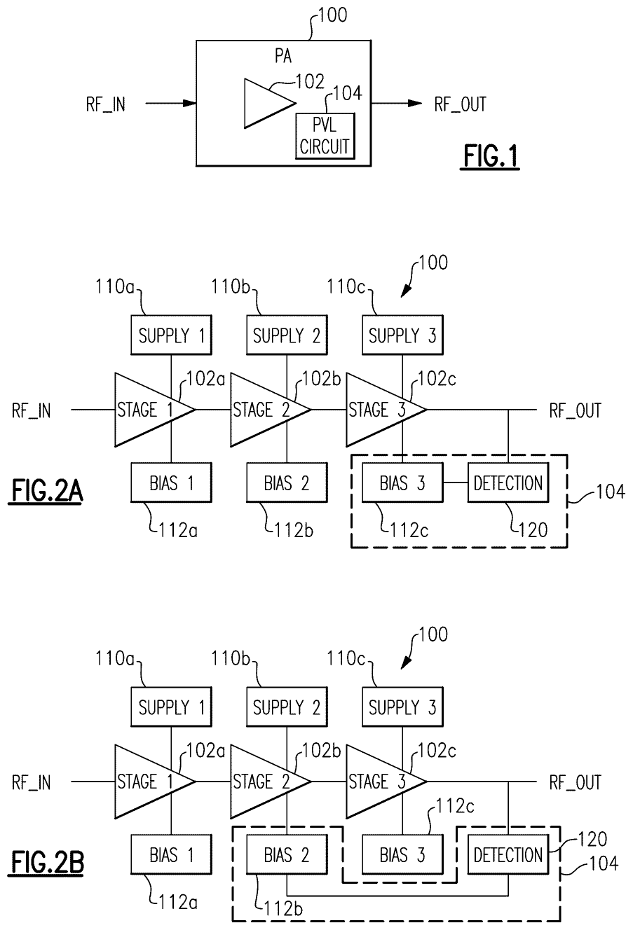

FIG. 1 depicts a power amplifier (PA) 100 having one or more amplification stages 102 configured to receive an input signal (RF_IN) and amplify it to generate an amplified signal (RF_OUT). Such a PA can include and/or be functionally coupled with a peak voltage limiting (PVL) circuit 104. Examples of such a PVL circuit are described herein in greater detail.

In some embodiments, and as described herein, a PVL circuit can be implemented as a closed loop system configured to a respond to a peak voltage condition at the output of an amplifier stage (e.g., output stage) to reduce the bias provided to that amplifier stage (e.g., output stage) to another stage (e.g., driver stage). With such a closed loop system, the gain of the output stage amplification can be adjusted to, for example, reduce the obtainable maximum voltage and thereby avoid damage to the output stage. As described herein, such a closed loop system can be configured to provide improved ruggedness functionality while having minimal or no effect on normal operating characteristics of the amplifier. In the context of bipolar junction transistors (BJTs), the foregoing reduced bias can be a reduced base current. Although some examples are described herein in the context of such BJTs, it will be understood that one or more features of the present disclosure can also be implemented in other types of amplifying transistors.

In some embodiments, one or more features of the present disclosure can be implemented in PAs utilizing a number of process technologies. For example, PAs based on silicon germanium (SiGe), gallium arsenide (GaAs), silicon-on-insulator (SOI), or any other semiconductor process can benefit from one or more features as described herein.

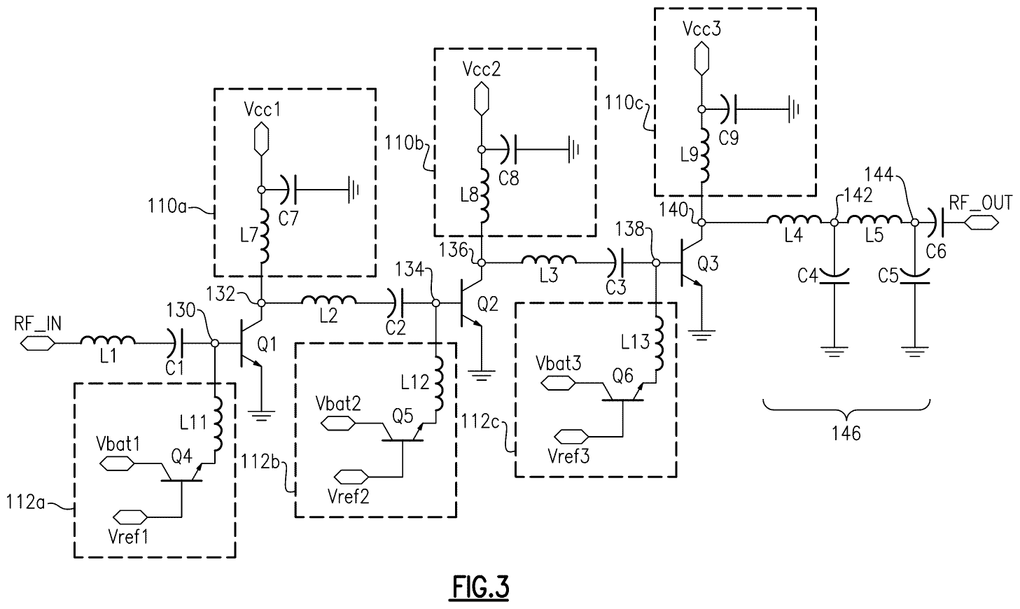

FIGS. 2A and 2B show examples of a PVL circuit 104 implemented for a PA system 100 having three amplification stages 102a-102c. An input signal RF_IN is shown to be provided to an input of the first stage 102a, and an output of the first stage 102a is shown to be provided to an input of the second stage 102b. Similarly, an output of the second stage 102b is shown to be provided to an input of the third stage 102c. An output of the third stage 102c is shown to yield an output RF_OUT of the RF system 100. Each of the three stages is shown to be coupled to a DC supply circuit (110a, 110b or 110c) and a bias circuit (112a, 112b or 112c).

In the example of FIG. 2A, the PVL circuit 104 can include a detection circuit 120 that couples the output of the last stage (102c) (e.g., the third stage in the three-stage example) with the bias circuit (112c) for the same stage. In the example of FIG. 2B, the PVL circuit 104 can include a detection circuit 120 that couples the output of the last stage (102c) (e.g., the third stage in the three-stage example) with the bias circuit (112b) for another stage (e.g., stage 102b). Examples of the two configurations are described herein in greater detail. It will be understood that other configurations can also be implemented. It will also be understood that although various examples are described herein in the context of three-stage PA systems, one or more features of the present disclosure can also be implemented in PA systems having different numbers of stages.

FIG. 3 shows an example of a PA system having three amplification stages, but without a ruggedness protection circuit. The three amplification stages are shown to be provided by amplifying transistors Q1, Q2 and Q3 (e.g., NPN bipolar junction transistors (BJTs)). More particularly, an input RF signal (RF_IN) is shown to be provided to the base of Q1 through a matching network which can include, for example, L1 and C1 in series. The output of Q1 is shown to be provided through the collector, to the base of Q2 through a matching network which can include, for example, L2 and C2 in series. Similarly, the output of Q2 is shown to be provided through the collector, to the base of Q3 through a matching network which can include, for example, L3 and C3 in series. The output of Q3 is shown to be provided through the collector, to the PA output (as RF_OUT) through an output matching network 146. Such an output matching network can include, for example, L4, L5 and C6 in series, and C4 and C5 coupling respective nodes 142, 144 to ground.

In the example of FIG. 3, each of Q1, Q2 and Q3 is shown to be provided with a supply voltage through the collector. More particularly, the collector node 132 of Q1 is shown to receive a supply voltage Vcc1 through a line element such as a choke inductance L7. The input node for the supply voltage Vcc1 is shown to be coupled to ground through C7. For the purpose of description, such a circuit for providing Vcc1 to the collector node 132 can be identified as 110a. Similarly, the collector node 136 of Q2 is shown to receive a supply voltage Vcc2 through a line element such as a choke inductance L8. The input node for the supply voltage Vcc2 is shown to be coupled to ground through C8. For the purpose of description, such a circuit for providing Vcc2 to the collector node 136 can be identified as 110b. Similarly, the collector node 140 of Q3 is shown to receive a supply voltage Vcc3 through a line element such as a choke inductance L9. The input node for the supply voltage Vcc3 is shown to be coupled to ground through C9. For the purpose of description, such a circuit for providing Vcc3 to the collector node 140 can be identified as 110c. It will be understood that the supply voltage circuits 110a-110c are examples, and that supply voltages can be provided to the amplification transistors in other configurations.

In the example of FIG. 3, each of Q1, Q2 and Q3 is shown to be provided with a base voltage at the base in an emitter-follower configuration. More particularly, the base node 130 of Q1 is shown to receive a bias signal from a bias circuit 112a so as to yield a base voltage Vbb1. The bias circuit 112a is shown to include Q4, with a reference voltage Vref1 being input into the base and the output of Q4 being provided through the emitter, and with Vbat1 supply voltage being provided to the collector. The output of Q4 is shown to be coupled to the base node 130 through a line element such as an inductance L11. Similarly, the base node 134 of Q2 is shown to receive a bias signal from a bias circuit 112b so as to yield a base voltage Vbb2. The bias circuit 112b is shown to include Q5, with a reference voltage Vref2 being input into the base and the output of Q5 being provided through the emitter, and with Vbat2 supply voltage being provided to the collector. The output of Q5 is shown to be coupled to the base node 134 through a line element such as an inductance L12. Similarly, the base node 138 of Q3 is shown to receive a bias signal from a bias circuit 112c so as to yield a base voltage Vbb3. The bias circuit 112c is shown to include Q6, with a reference voltage Vref3 being input into the base and the output of Q6 being provided through the emitter, and with Vbat3 supply voltage being provided to the collector. The output of Q6 is shown to be coupled to the base node 138 through a line element such as an inductance L13. In the example of FIG. 3, each of the inductances L11, L12, L13 can be configured to provide, for example, isolating functionality to isolate the corresponding bias circuit from the RF signal passing through the corresponding stage of amplification.

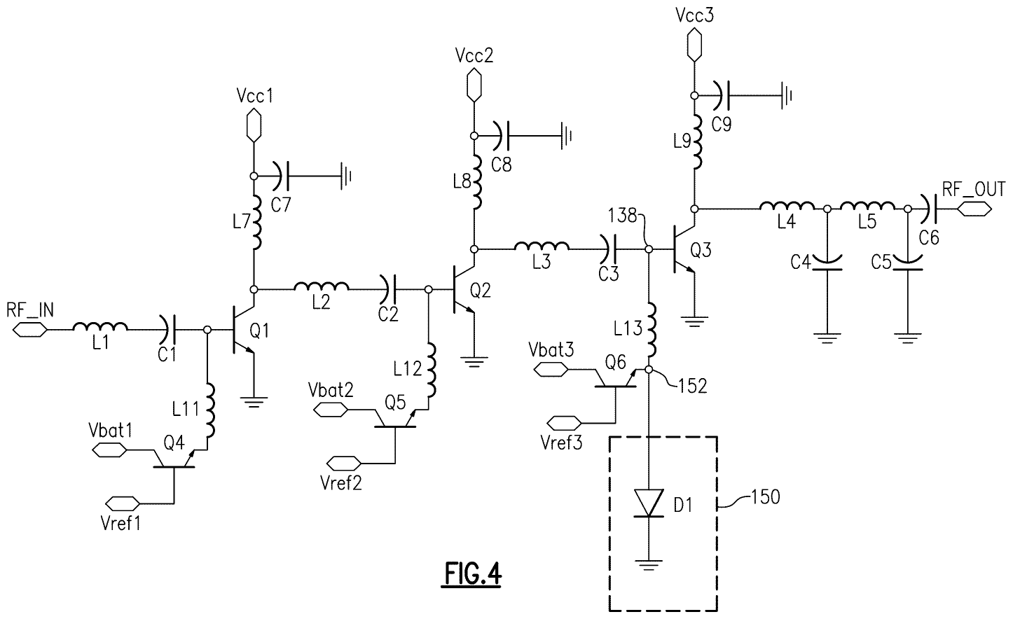

FIG. 4 shows an example of a ruggedness protection circuit 150 implemented in the context of the example PA system of FIG. 3. The ruggedness protection circuit 150 is shown to include a diode D1 that couples node 152 to ground. The node 152 is coupled to the base node 138 of Q3, and accordingly, the diode coupling to ground can provide current sink functionality in which the diode D1 starts to conduct current away from the base to thereby prevent the current participating in or having a multiplicative avalanche effect within Q3 when the collector node of Q3 experiences a high voltage such as a peak voltage excursion event in Q3. It is noted, however, that such a ruggedness protection circuit typically leads to a trade-off with normal operating performance parameters such as power-added efficiency (PAE) and/or error vector magnitude (EVM).

In some implementations, the present disclosure relates to a peak voltage limiting (PVL) circuit that can provide effective ruggedness protection functionality while having little or no effect on normal operating performance. As described herein, such a PVL circuit can be configured to detect a condition where a peak voltage at a collector of an amplifying transistor (e.g., of an output stage) exceeds some selected value. When such a condition is detected, the PVL circuit can reduce the base voltage Vbb of an amplifying transistor by activating a sink for the base current. As described herein, such an amplifying transistor for which Vbb is reduced may or may not be the same amplifying transistor at which the exceeding peak voltage condition is detected. For example, in the context of a 3-stage configuration, the exceeding peak voltage condition can be detected at the collector of the last stage (stage 3), and the stage for which Vbb is reduced in response can be stage 3 or another stage such as stage 2.

FIG. 5 shows that in some embodiments, the foregoing PVL circuit can include a group of one or more diodes arranged in series (indicated as 160) that couples a collector of the amplifying transistor (for which exceeding peak voltage condition is being detected) to a transistor that can be activated to provide sinking of base current of the amplifying transistor (for which Vbb is being reduced). Such a reduction in Vbb results in reduction of gain and drive power capability of the amplifying transistor, to thereby reduce the peak voltage at the collector as a result of a smaller RF signal on that node.

In FIG. 5, the peak voltage being detected is indicated as Vcc, and the transistor for sinking of the base current (sometimes referred as a sinking transistor) is shown to have its base coupled to the output of the group of N diode(s) 160 (where N is a positive integer). The sinking transistor is shown to have its collector coupled to a node representative of the base voltage (Vbb) being reduced, and its emitter coupled to ground.

In FIG. 5, a resistance R is shown to be provided in series with the group of N diode(s) 160. In some embodiments, one or more circuit elements such as an inductance can replace the resistance R, or be implemented with the resistance R. In some embodiments, the number of diodes (N), R, and/or other circuit element(s) can be selected to, for example, set the selected voltage to facilitate the foregoing Vbb-reduction functionality. In some embodiments, such a selected voltage can be based on, for example, a conduction onset voltage associated with the group of N diode(s) 160. Such conduction onset voltage can be based on degree and exponential rise in current conducted through the diode(s) as voltage builds on the collector node. In some embodiments, such an exponential nature of the diode curve can be utilized to provide a clamping effect on the voltage that manifests on the collector node, using a negative feedback loop back to transistor bias condition(s) on one or more amplification stages.

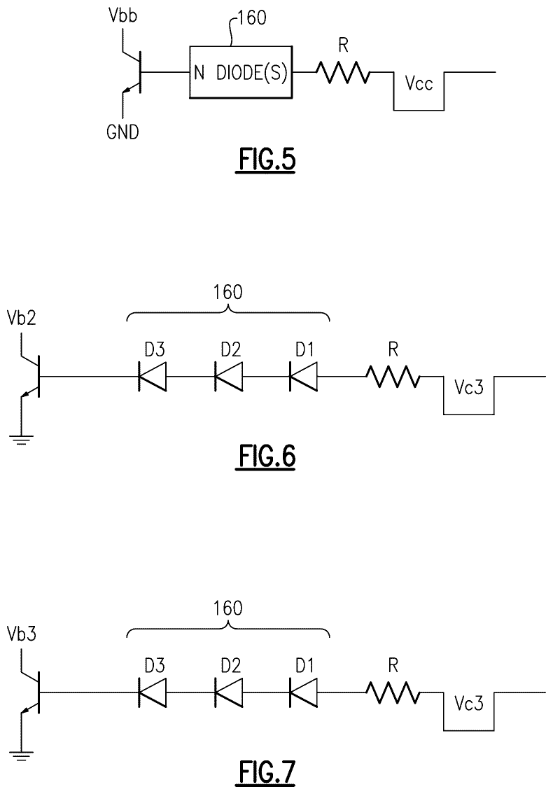

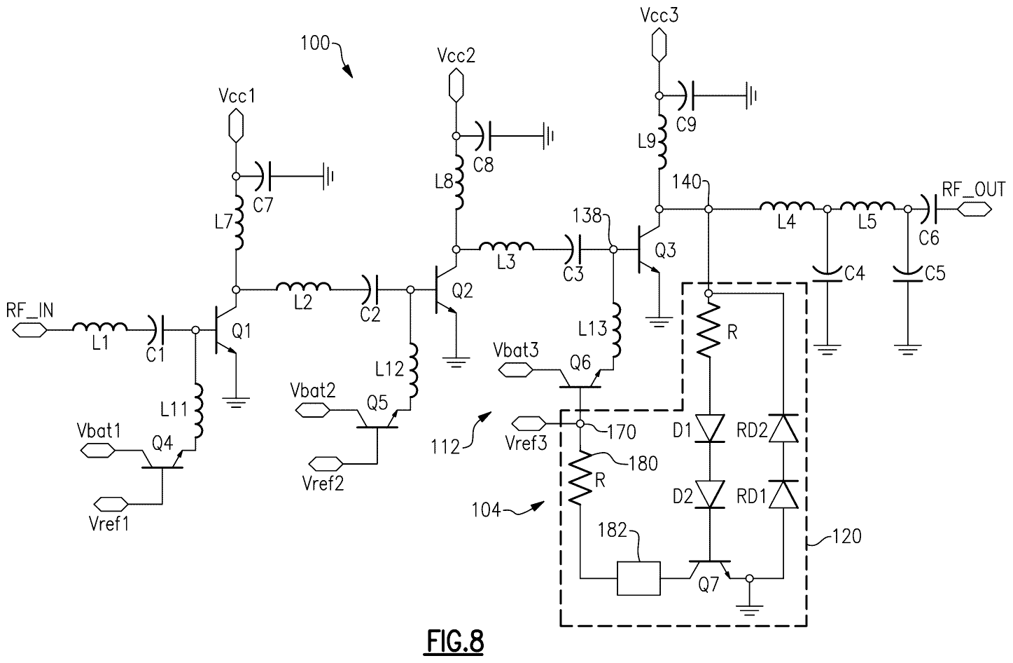

As described herein, an amplifying transistor for which Vbb is reduced may or may not be the same amplifying transistor at which peak voltage condition is being detected. FIG. 6 shows a more specific example of the peak voltage detection configuration of FIG. 5, where peak voltage (Vc3) is detected at the collector of the last stage (in a 3-stage example) and such a such voltage is routed to a sinking transistor (when the diodes 160 are turned ON) so as to reduce the base voltage Vb2 of the second stage. FIG. 7 shows another more specific example of the peak voltage detection configuration of FIG. 5, where peak voltage (Vc3) is detected at the collector of the last stage (in a 3-stage example) and such a such voltage is routed to a sinking transistor (when the diodes 160 are turned ON) so as to reduce the base voltage Vb3 of the same third stage. Examples of both of the configurations of FIGS. 6 and 7 are described herein in greater detail.

Some example circuits described herein can comprise various components configured to suppressed spurs and/or limit spur generation. In some cases, spurs may be generated due at least in part to a PVL diode stack turning on.

FIGS. 8-11 show examples where PVL circuits 104 are implemented in different manners in an example 3-stage PA system described herein in reference to FIG. 3. Accordingly, details concerning the three stages and their respective supply circuits and bias circuits can be found herein in reference to FIG. 3.

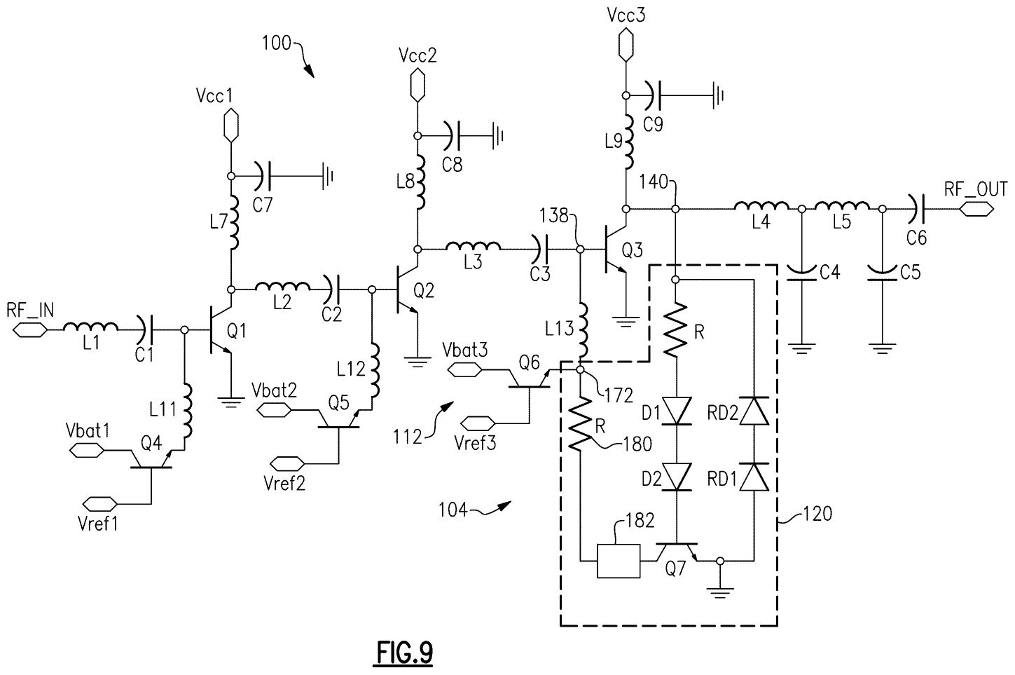

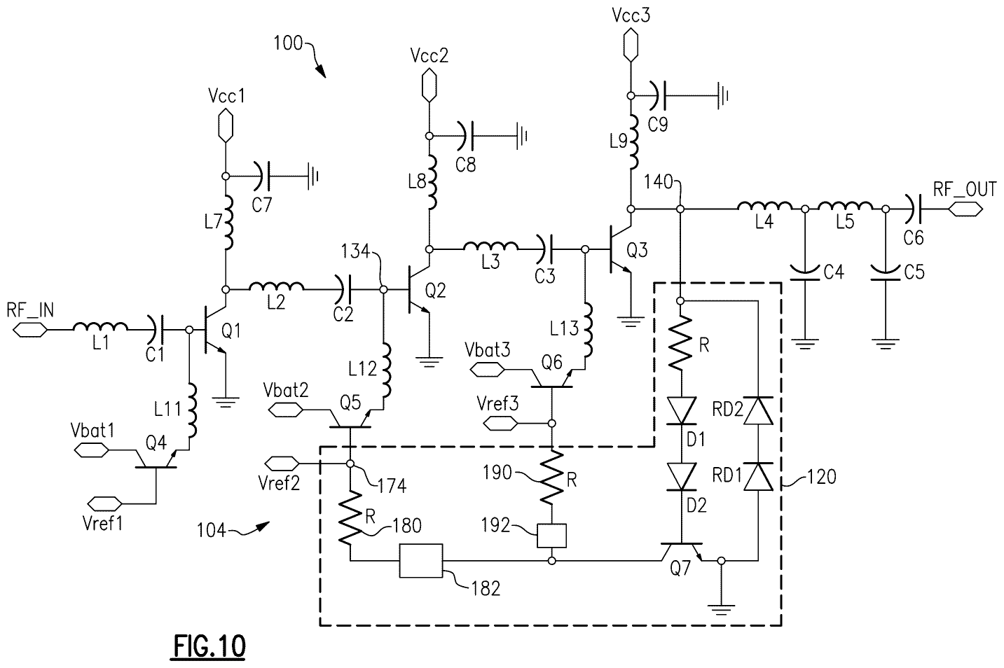

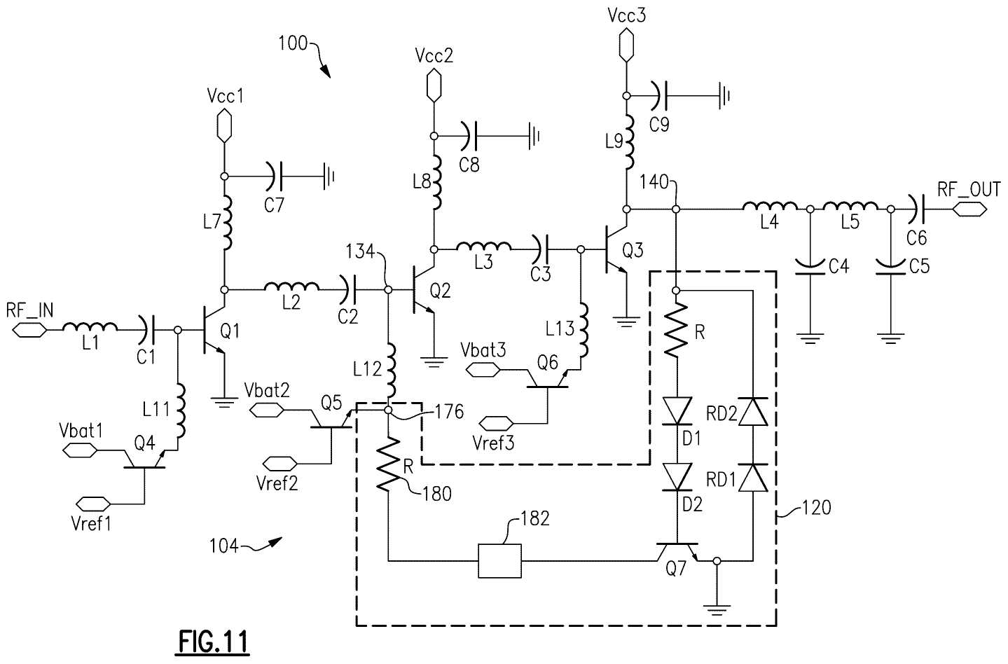

In each example of FIGS. 8 and 9, a PVL circuit 104 includes a detection circuit 120 that couples the collector node 140 of the third stage amplifier Q3 to the bias circuit 112 for the same third stage amplifier Q3. In each example of FIGS. 10 and 11, a PVL circuit 104 includes a detection circuit 120 that couples the collector node 140 of the third stage amplifier Q3 to the bias circuit 112 for the second stage amplifier Q2. The bias circuit 112 may comprise a transistor (Q6) and/or a battery voltage (Vbat3) coupled to a collector of the transistor, a reference voltage (Vref3) coupled to a base of the transistor, and/or an inductor (L13) coupled to an emitter of the transistor. The base of the transistor may be coupled to the detection circuit 120 and/or an isolation resistor 180 of the detection circuit 120.

In each of the four examples of FIGS. 8-11, the detection circuit 120 includes a series circuit having a resistance R and a diode circuit including a group of diodes (depicted as D1 and D2), and a sinking transistor Q7. The group of diodes can comprise more than two diodes. More particularly, the series circuit (R, D1 and D2) is shown to couple the collector node 140 and the base of the sinking transistor Q7. The emitter of Q7 is grounded, and the collector of Q7 is coupled to the respective bias circuit. It will be understood that the detection circuit 120 can include more or a smaller number of diodes. It will also be understood that the resistance R can be replaced with or be supplemented with one or more circuit elements such an inductance.

In the example of FIG. 8, the detection circuit 120 is shown to couple the collector node 140 of the third stage amplifier Q3 to the bias circuit of the same third stage amplifier Q3. More particularly, the collector of the sinking transistor Q7 is shown to be coupled to the reference voltage (Vref3) node 170 of the emitter-follower bias circuit for the third stage amplifier Q3. Accordingly, when the sinking transistor Q7 is turned ON through the diodes D1, D2 by a peak voltage condition, current can be diverted from the reference voltage (Vref3) node 170 to ground through Q7, thereby reducing the voltage (Vb3) provided to the base node 138 of the third stage amplifier Q3.

In the example of FIG. 9, the detection circuit 120 is shown to couple the collector node 140 of the third stage amplifier Q3 to the bias circuit of the same third stage amplifier Q3. More particularly, the collector of the sinking transistor Q7 is shown to be coupled to the emitter node 172 of Q6 of the emitter-follower bias circuit for the third stage amplifier Q3. Accordingly, when the sinking transistor Q7 is turned ON through the diodes D1, D2 by a peak voltage condition, current can be diverted from the emitter node 172 to ground through Q7, thereby reducing the voltage (Vb3) provided to the base node 138 of the third stage amplifier Q3.

In the example of FIG. 10, the detection circuit 120 is shown to couple the collector node 140 of the third stage amplifier Q3 to the bias circuit of the second stage amplifier Q2. More particularly, the collector of the sinking transistor Q7 is shown to be coupled to the reference voltage (Vref2) node 174 of the emitter-follower bias circuit for the second stage amplifier Q2. Accordingly, when the sinking transistor Q7 is turned ON through the diodes D1, D2 by a peak voltage condition, current can be diverted from the reference voltage (Vref2) node 174 to ground through Q7, thereby reducing the voltage (Vb2) provided to the base node 134 of the second stage amplifier Q2.

In the example of FIG. 11, the detection circuit 120 is shown to couple the collector node 140 of the third stage amplifier Q3 to the bias circuit of the second stage amplifier Q2. More particularly, the collector of the sinking transistor Q7 is shown to be coupled to the emitter node 176 of Q5 of the emitter-follower bias circuit for the second stage amplifier Q2. Accordingly, when the sinking transistor Q7 is turned ON through the diodes D1, D2 by a peak voltage condition, current can be diverted from the emitter node 176 to ground through Q7, thereby reducing the voltage (Vb2) provided to the base node 134 of the second stage amplifier Q2.

As shown in each of the four examples of FIGS. 8-11, the detection circuit 120 may comprise one or more components configured to suppress spur generation of the PVL circuit 104. For example, the detection circuit 120 can comprise a first isolation resistor 180 directly coupled to the reference voltage (Vref3) node 170 of FIG. 8 and/or a base of the Q6 transistor, the emitter node 172 of FIG. 9 and/or an emitter of the Q6 transistor, the reference voltage (Vref2) node 174 and/or a base of the Q5 transistor of FIG. 10, and/or the emitter node 176 and/or emitter of the Q5 transistor of FIG. 11.

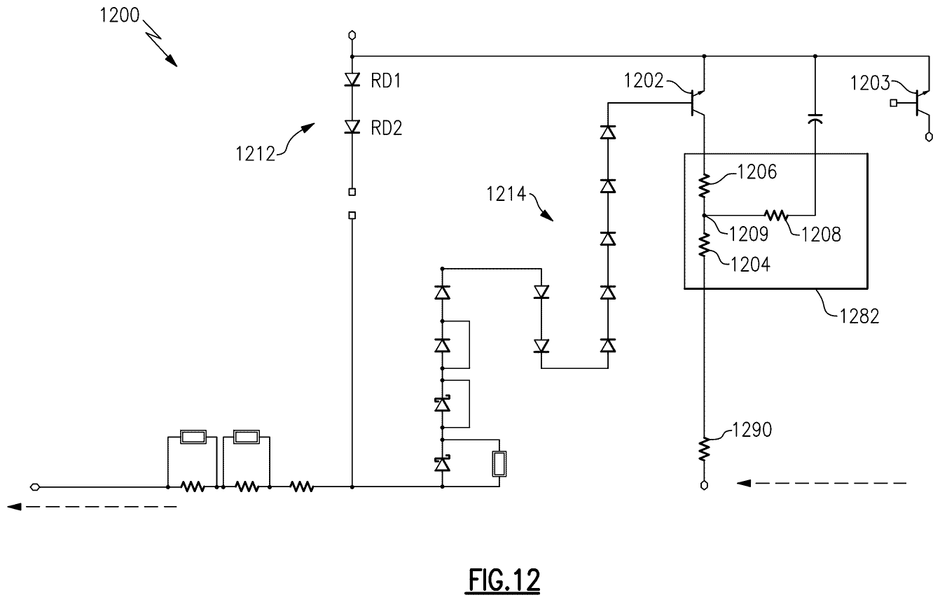

The first isolation resistor 180 may be directly coupled to a first attenuation circuit 182, which may comprise one or more resistors (see, e.g., FIG. 12). For example, the first attenuation circuit 182 can comprise three resistors coupled together at a central node. The first attenuation circuit 182 may be directly coupled to the Q7 transistor and/or a collector of the Q7 transistor.

In some examples, the detection circuit 120 may comprise a reverse diode circuit including a first reverse diode (RD1) 184 and/or a second reverse diode (RD2) 186 configured to protect the circuit PVL circuit 104 against reverse voltage swing. RD1 184 may be directly coupled to an emitter of the Q7 transistor and/or to ground. In some examples, an anode of RD1 184 may be coupled to Q7 and/or ground. An anode of RD2 186 may be directly coupled to a cathode of RD1 184. A cathode of RD2 186 may be coupled to the collector node 140 of the Q3 transistor.

The detection circuit 120 may comprise a second isolation resistor 190 and/or a second attenuation circuit 192, as shown in FIG. 10. For example, the second isolation resistor 190 may be directly coupled to a base of the Q6 transistor and/or the second attenuation circuit 192 may be coupled between the second isolation resistor 190 and the collector of the Q7 transistor. The first attenuation circuit 182 may be directly coupled to the second attenuation circuit 192.

FIG. 12 illustrates an example PVL circuit 1200 comprising one or more components in accordance with one or more examples described herein. The circuit 1200 may comprise an attenuation circuit 1282 directly coupled to an isolation resistor 1290 and/or a first transistor 1202 (e.g., Q7 in FIG. 8). The attenuation circuit 1282 may comprise a first resistor 1204, a second resistor 1206, and/or a third resistor 1208. The first resistor 1204, second resistor 1206, and/or third resistor 1208 may be coupled together at a first node 1209. The first resistor 1204 and the second resistor 1206 may be coupled in series between the isolation resistor 1290 and the first transistor 1202 (e.g., a collector of the first transistor 1202). The third resistor 1208 may be coupled to an emitter of the first transistor 1202 and/or to an emitter of a second transistor 1203.

The emitter of the first transistor 1202 may be coupled to a first diode network 1212 comprising one or more series-connected reverse diodes. For example, the emitter of the first transistor 1202 may be coupled to an anode of one or more diodes of the first diode network 1212. A base of the first transistor 1202 may be directly coupled to a second diode network 1214 comprising two or more series-connected forward diodes. For example, the base of the first transistor 1202 may be coupled to a cathode of one or more diodes of the second diode network 1214.

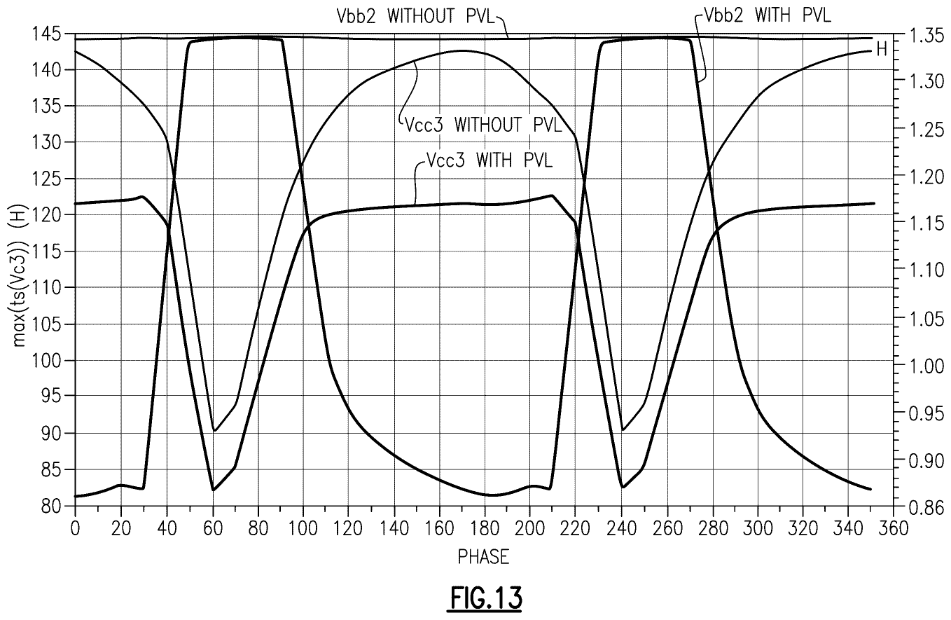

FIG. 13 shows an example of how a collector voltage Vcc3 can be advantageously limited by a PVL circuit having one or more features as described herein. In FIG. 13, Vcc3 (with a vertical axis scale on the left) curves (with and without PVL functionality) are plotted as a function of phase. Also plotted are Vbb2 curves (with a vertical axis scale on the right) for the configurations with and without PVL functionality.

In the example of FIG. 13, Vbb2 remains approximately constant without the PVL functionality. Accordingly, Vcc3 is shown to reach relatively high peak values above 14 volts, thereby increasing the likelihood of breakdown.

With the PVL functionality, Vbb2 is shown to decrease when Vcc3 exceeds some selected value (e.g., about 12 volts). With such a decrease in Vbb2, Vcc3 is shown to be limited to a level slightly above the selected value. Accordingly, the limited Vcc3 level can decrease the likelihood of breakdown. It is further noted that when Vcc3 decreases below the selected value, Vbb2 is allowed to increase to its original level, thereby allowing normal operation.

In some embodiments, one or more features of the present disclosure can be utilized to limit the collector current instead of the collector voltage (e.g., Vcc3). However, as shown in the example of FIG. 13, the phase of Vcc3 with PVL is the same as or close to the phase of Vcc3 associated with normal operation. Accordingly, limiting the collector voltage can be preferable in many RF applications.

A PVL circuit having one or more features as described herein can be utilized as an effective ruggedness protection circuit. In some embodiments, such a desirable functionality can be realized without significantly degrading other performance parameters associated with a PA.

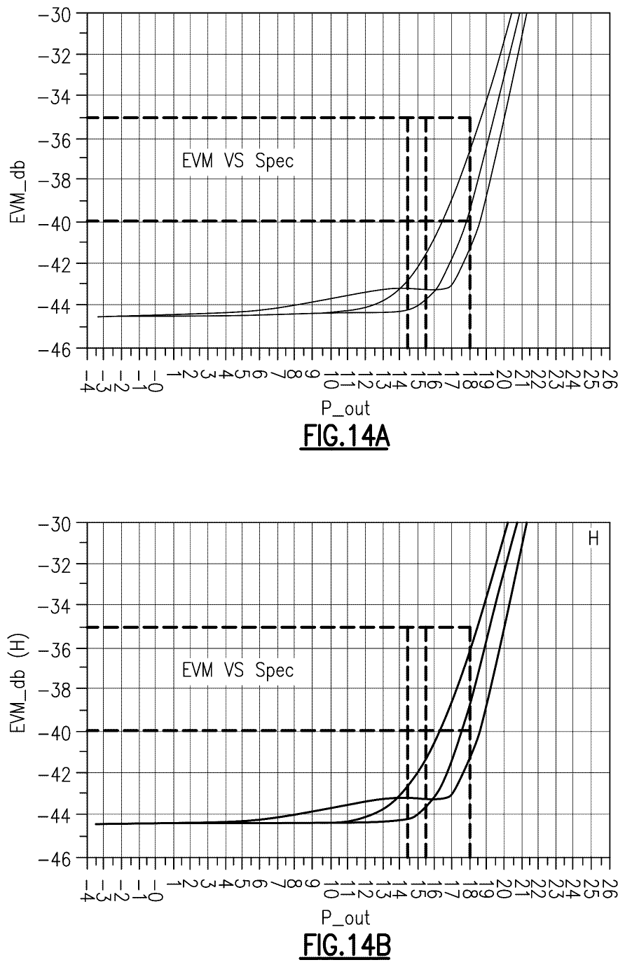

For example, FIGS. 13 and 14 show examples of performance with and without a PVL circuit. More particularly, FIG. 14A shows EVM performance plots without a PVL circuit, and FIG. 14B shows EVM performance plots with a PVL circuit. One can see that EVM performance is generally not degraded by the presence of the PVL circuit.

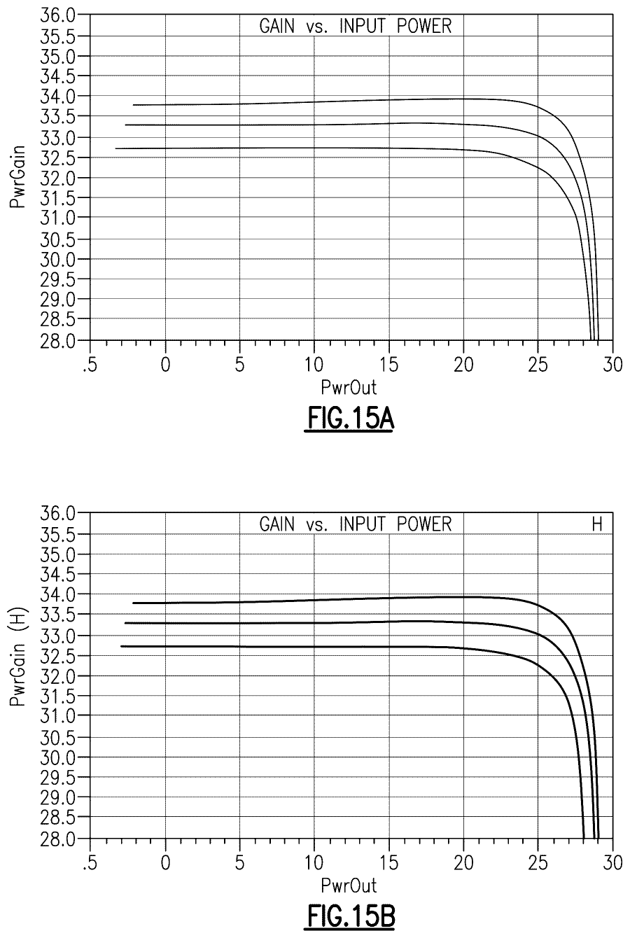

Similarly, FIG. 15A shows gain profiles without a PVL circuit, and FIG. 15B shows gain profiles with a PVL circuit. One can see that gain performance is generally not degraded by the presence of the PVL circuit.

In some embodiments, a PA having a PVL circuit as described herein can provide a number of advantageous features. Such features can include, for example, a smaller circuit while providing effective ruggedness protection, little or no hysteresis effect associated with operation of the PVL circuit, relatively quick response to high voltage excursions at collectors, and little or no degradation of the PA's normal operating characteristics.

In some embodiments, a PVL circuit as described herein can be implemented as a closed loop feedback system. Such a PVL circuit can be implemented in PAs that utilize different process technologies. For example, one or more features of the present disclosure can be implemented for NPN type amplifying transistors that are based on different process technologies as described herein.

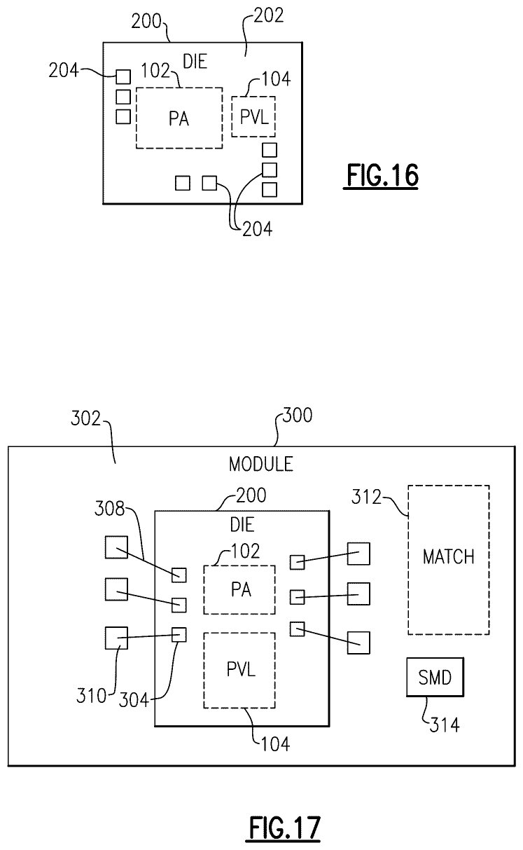

FIG. 16 depicts a die 200 that can include a PVL circuit 104 having one or more features as described herein. The semiconductor die 200 can include a substrate 202. In some embodiments, a power amplifier (PA) circuit 102 (e.g., SiGe or GaAs devices) can also be implemented on the substrate 202. A plurality of connection pads 204 can also be formed on the substrate 202 to provide, for example, power and signals for the PA circuit 102.

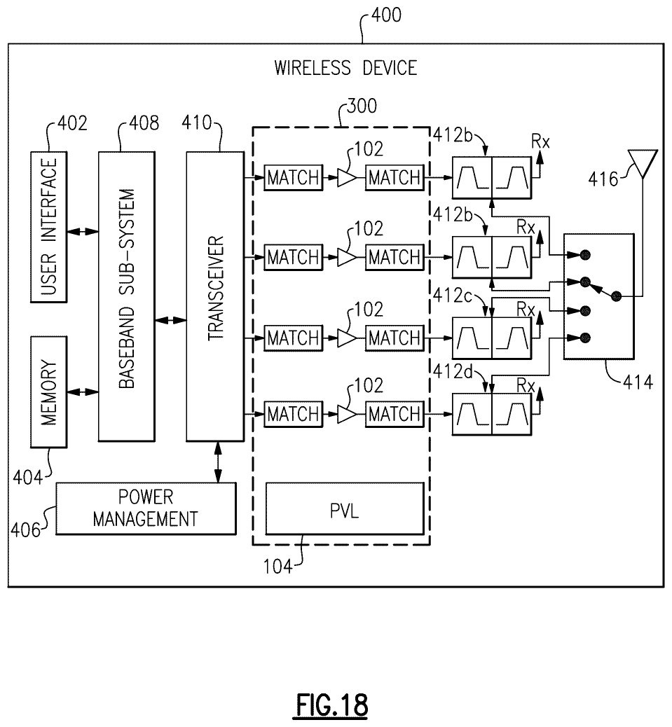

In some implementations, one or more features described herein can be included in a module. FIG. 17 schematically depicts an example module 300 having a packaging substrate 302 that is configured to receive a plurality of components. In some embodiments, such components can include a die 200 having one or more featured as described herein. For example, the die 200 can include a PA circuit 102 and a PVL circuit 104. A plurality of connection pads 304 can facilitate electrical connections such as wirebonds 308 to connection pads 310 on the substrate 302 to facilitate passing of various power and signals to and from the die 200.

In some embodiments, other components can be mounted on or formed on the packaging substrate 302. For example, one or more surface mount devices (SMDs) (314) and one or more matching networks (322) can be implemented. In some embodiments, the packaging substrate 302 can include a laminate substrate.

In some embodiments, the module 300 can also include one or more packaging structures to, for example, provide protection and facilitate easier handling of the module 300. Such a packaging structure can include an overmold formed over the packaging substrate 302 and dimensioned to substantially encapsulate the various circuits and components thereon.

It will be understood that although the module 300 is described in the context of wirebond-based electrical connections, one or more features of the present disclosure can also be implemented in other packaging configurations, including flip-chip configurations.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc.

FIG. 18 schematically depicts an example wireless device 400 having one or more advantageous features described herein. One or more PAs 102 as described herein can utilize one or more PVL circuits 104 as described herein. In embodiments where the PAs 102 and their PVL circuit(s) 104 are packaged into a module, such a module can be represented by a dashed box 300. In some embodiments, the module 300 can include at least some of input and output matching circuits.

The PAs 102 can receive their respective RF signals from a transceiver 410 that can be configured and operated in known manners to generate RF signals to be amplified and transmitted, and to process received signals. The transceiver 410 is shown to interact with a baseband sub-system 408 that is configured to provide conversion between data and/or voice signals suitable for a user and RF signals suitable for the transceiver 410. The transceiver 410 is also shown to be connected to a power management component 406 that is configured to manage power for the operation of the wireless device 400. Such power management can also control operations of the baseband sub-system 408 and the module 300.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, outputs of the PAs 102 are shown to be matched and routed to an antenna 416 via their respective duplexers 412a-412d and a band-selection switch 414. The band-selection switch 414 can be configured to allow selection of, for example, an operating band or an operating mode. In some embodiments, each duplexer 412 can allow transmit and receive operations to be performed simultaneously using a common antenna (e.g., 416). In FIG. 18, received signals are shown to be routed to “Rx” paths (not shown) that can include, for example, a low-noise amplifier (LNA).

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A circuit comprising:
a first diode circuit coupled to an output of an amplification stage of a power amplifier (PA);
a first bias circuit;
a first isolation resistor coupled to the first bias circuit;
a first attenuation circuit coupled to the first isolation resistor, the first attenuation circuit comprising two or more resistors; and
a sink transistor coupled to the first diode circuit and the first attenuation circuit.

2. The circuit of claim 1 further comprising a second diode circuit coupled to an emitter of the sink transistor.

3. The circuit of claim 2 wherein the second diode circuit comprises a first diode, and wherein the emitter of the sink transistor is coupled to an anode of the first diode.

4. The circuit of claim 3 wherein the first diode circuit comprises a second diode, and wherein a base of the sink transistor is coupled to a cathode of the second diode.

5. The circuit of claim 1 wherein the first attenuation circuit is coupled to a collector of the sink transistor.

6. The circuit of claim 1 wherein the first attenuation circuit comprises a first resistor, a second resistor, and a third resistor, and wherein each of the first resistor, second resistor, and third resistor is coupled to a first node.

7. The circuit of claim 1 wherein the first bias circuit comprises a bias transistor, and wherein the first isolation resistor is coupled to a base of the bias transistor.

8. The circuit of claim 7 further comprising a second bias circuit, a second isolation resistor, and a second attenuation circuit, wherein the second bias circuit is coupled to the second isolation resistor, the second isolation resistor is coupled to the second attenuation circuit, and the second attenuation circuit is coupled to the sink transistor.

9. The circuit of claim 1 wherein the first bias circuit comprises a bias transistor, and wherein the first isolation resistor is coupled to an emitter of the bias transistor.

10. The circuit of claim 1 wherein the first diode circuit is configured to provide a conductive path from the output when an output voltage exceeds a selected value.

11. The circuit of claim 10 wherein the sink transistor is configured to reduce a bias voltage provided by the first bias circuit when the output voltage exceeds the selected value.

12. A power amplifier (PA) comprising:
a first diode circuit coupled to an output of an amplification stage;
a first bias circuit;
a first isolation resistor coupled to the first bias circuit;
a first attenuation circuit coupled to the first isolation resistor, the first attenuation circuit comprising two or more resistors; and
a sink transistor coupled to the first diode circuit and the first attenuation circuit.

13. The PA of claim 12 further comprising a second diode circuit coupled to an emitter of the sink transistor.

14. The PA of claim 12 wherein the first attenuation circuit is coupled to a collector of the sink transistor.

15. The PA of claim 12 wherein the first attenuation circuit comprises a first resistor, a second resistor, and a third resistor, and wherein each of the first resistor, second resistor, and third resistor is coupled to a first node.

16. The PA of claim 12 wherein the first bias circuit comprises a bias transistor, and wherein the first isolation resistor is coupled to a base of the bias transistor.

17. A radio-frequency (RF) module comprising:
a packaging substrate configured to receive a plurality of components; and
a power amplifier (PA) implemented on a die that is mounted on the packaging substrate, the PA including one or more amplification stages configured to amplify an RF signal, the PA further including a first diode circuit coupled to an output of an amplification stage of the one or more amplification stages, a first bias circuit, a first isolation resistor coupled to the first bias circuit, a first attenuation circuit coupled to the first isolation resistor, the first attenuation circuit comprising two or more resistors, and a sink transistor coupled to the first diode circuit and the first attenuation circuit.

18. The RF module of claim 17 further comprising a second diode circuit coupled to an emitter of the sink transistor.

19. The RF module of claim 17 wherein the first attenuation circuit is coupled to a collector of the sink transistor.

20. The RF module of claim 17 wherein the first attenuation circuit comprises a first resistor, a second resistor, and a third resistor, and wherein each of the first resistor, second resistor, and third resistor is coupled to a first node.
